(19) United States
(12) Patent Application Publication
(10) Pub. No.: US 2003/0153170 A1
(43) Pub. Date: Aug. 14, 2003

(54) Method for cleaning semiconductor device and method for fabricating the same

(75) Inventor: Yukihisa Wada, Kyoto (JP)

Correspondence Address: NIXON PEABODY, LLP, 8180 GREENSBORO DRIVE, SUITE 800, MCLEAN, VA, 22102, US

(73) Assignee: Matsushita Electric Industrial Co., Ltd., Kadoma-shi (JP)

(21) Appl. No.: 10/292,903

(22) Filed: Nov. 13, 2002

(30) Foreign Application Priority Data
Nov. 14, 2001 (JP) 2001-348200

(51) Int. Cl. H01L 21/3205; H01L 21/4763

(52) U.S. Cl. 438/595

(57) ABSTRACT

A sidewall of a CVD oxide film is formed on a side face of a gate electrode formed on a semiconductor substrate. Then, with the sidewall exposed, the semiconductor substrate is cleaned such that the CVD oxide film has an etch selectivity of 5 or less with respect to a thermal oxide film.

### BACKGROUND OF THE INVENTION

The present invention relates to methods for cleaning semiconductor devices and methods for fabricating the same, and more particularly relates to cleaning methods employed in processes for fabricating CMOS transistors.

Recently, very-large-scale integration (VLSI) has been reduced in size, resulting in that reduction in thickness or deformation of processed films can no more be disregarded during cleaning steps in fabrication processes.

In the process of fabricating a CMOS transistor, at each of stages such as polymer removal, resist removal, and pre-cleaning before annealing (i.e., pre-furnace cleaning), performed between the formation of a sidewall with a lightly-doped drain (LDD) structure and the formation of a silicide layer to be a contact region, the following cleaning methods have been conventionally used. First, at the first step, a resist or organic matter is removed by cleaning with a sulfuric acid-hydrogen peroxide mixture (SPM) solution, which is a liquid mixture of sulfuric acid and hydrogen peroxide solution. Next, at the second step, an underlying film is etched by cleaning with an ammonium-hydrogen peroxide mixture (APM) solution, which is a liquid mixture of ammonia water and hydrogen peroxide solution, thereby lifting off the surface of the underlying film to remove particles attached to the surface. That is to say, a semiconductor device is cleaned through combined cleaning in which the SPM cleaning at the first step and the APM cleaning at the second step are performed in combination (hereinafter also referred to as SPM+APM cleaning).

However, if the known SPM+APM cleaning is used in a cleaning process performed between the formation of a sidewall and the formation of a silicide layer, a chemical vapor deposited (CVD) oxide film forming the sidewall is etched by the APM cleaning, resulting in erosion of the sidewall. This is because implantation damage is caused on the CVD oxide film forming the sidewall during impurity implantation for forming source/drain regions performed after the formation of the sidewall, so that the CVD oxide film becomes more susceptible to etching than before the impurity implantation. When the sidewall is eroded, the silicide layer formed on the respective surfaces of the source/drain regions is enlarged toward the gate electrode. Accordingly, there might arise a problem that the more the semiconductor device is downsized, the more easily a leakage current is caused between the gate electrode and the source or drain region.

On the other hand, if the CVD oxide film is less etched for the purpose of reducing the erosion of the sidewall during the APM cleaning, the sidewall is less eroded, but there arises another problem of decrease in capability of cleaning for removing a polymer, resist residues or particles, for example, created through dry etching.

### SUMMARY OF THE INVENTION

It is therefore an object of the present invention to achieve, in a process for fabricating a very small semiconductor device including a sidewall with an LDD structure, both prevention of a leakage current caused by erosion of the CVD oxide film that forms the sidewall, and reliable cleaning of the semiconductor device.

To achieve the object described above, the present inventor has examined etch rates of CVD oxide films in various cleaning methods (a first study). The result of this examination is shown in [Table 1].

TABLE 1

| | etch rate of | etch rate of | etch rate of BPSG |
|---|---|---|---|
| | th-SiO₂ (900° C. pyro) | TEOS (680° C.) | (B/P = 3.917% 48O° C.) |
| APM | 0.04 nm/min. | 0.26 nm/min. | 1.53 nm/min. |
| 1:1:40 50° C. | | | |
| HF | 0.22 nm/min. | 2.43 nm/min. | 4.05 nm/min. |
| 0.1% 23° C. | | | |
| BHF | 2.30 nm/min. | 5.28 nm/min. | 5.84 nm/min. |
| 0.1% HF | | | |
| 40% NH₄F 23° C. | | | |
| TMAH | 0.01 nm/min. | 0.04 nm/min. | 0.10 nm/min. |
| 2% 23° C. | | | |

The first study was performed on cleaning methods using, respectively, an APM solution (1:1:40 ammonium, hydrogen peroxide solution and water proportions by volume; 50° C. cleaning temperature), hydrofluoric acid (HF) aqueous solution (0.1% HF concentration by volume; 23° C. cleaning temperature), a buffered hydrofluoric acid (BHF) aqueous solution (0.1% HF concentration by volume; 40% ammonium fluoride (NH₄F) concentration by volume; 23° C. cleaning temperature), and a tetramethylammonium hydroxide (TMAH) aqueous solution (2% TMAH concentration by volume; 23° C. cleaning temperature). As the CVD oxide films, a silicon oxide film formed by a CVD process using a tetra ethyl ortho silicate (TEOS)-based gas (hereinafter referred to as a TEOS film) and a boron-phosphorous silicate glass (BPSG) film were used. The etch rate of a thermal oxide film (hereinafter also referred to as a th-SiO₂ film) in each of the cleaning methods described above was also examined for reference. Specifically, the TEOS film was deposited to a thickness of 100 nm at a temperature of 680° C. The BPSG film was formed to a thickness of 500 nm by adding boron and phosphorus at concentrations of 3.9% and 7.0% by mass, respectively, at a temperature of 480° C. and then was baked by performing rapid thermal annealing (RTA) at a temperature of 800° C. for 10 seconds. The th-SiO₂ film was formed to a thickness of 10 nm by performing pyrogenic oxidation at a temperature of 900° C.

Next, the present inventor has examined etch selectivities of the CVD oxide films with respect to the th-SiO₂ film (i.e., the ratios of the respective etch rates of the CVD oxide films to the etch rate of the th-SiO₂ film) in various cleaning methods (a second study). The result of this examination is shown in [Table 2].

TABLE 2

| | | etch selectivity of |
|---|---|---|
| | etch selectivity of | BPSG(B/P = 3.9/7% |
| | TEOS (680° C.) to | 480° C.) to th-SiO₂ |
| | th-SiO₂ (900° C. pyro) | (900° C. pyro) |
| APM | 6.4 | 38.3 |
| 1:1:40 50° C. | | |
| HF | 11.0 | 18.4 |
| 0.1% 23° C. | | |
| BHF | | |
| 0.1% HF | 2.3 | 2.5 |
| 40%NH4F 23° C. | | |
| SPM(5:1 120° C. | | |
| 10 min.) + APM(1:1:40 | 6.4 | 38.3 |
| 50° C. 10 min.) | | |
| BHF(0.1% HF | | |
| 40% NH₄F 23° C. | | |
| 12 s.) + O₃(5 ppm 23° C. | 2.4 | 2.9 |
| 3 min.) + TMAH(2% | | |
| 23° C. 2 min.) | | |

The second study was performed on: the cleaning methods using the APM solution, the HF aqueous solution and the BHF aqueous solution, respectively; a cleaning method using a combination of a SPM solution (5:1 concentrated sulfuric acid and hydrogen peroxide solution proportions by volume; 120° C. cleaning temperature; 10 min. cleaning time) and an APM solution (10 min. cleaning time); and a cleaning method using a combination of a BHF aqueous solution (12 sec. cleaning time), an ozone (O₃)-containing water (5 ppm O₃ concentration; 23° C. cleaning temperature; 3 min. cleaning time) and a TMAH aqueous solution (23° C. cleaning temperature, 2 min. cleaning time). In the second study, the compositions of and the cleaning temperatures for the respective APM solution, HF aqueous solution, BHF aqueous solution and TMAH aqueous solution are the same as those in the first study. As the CVD oxide films, the TEOS film and the BPSG film used in the first study were also used. The same th-SiO₂ film as that used in the first study was also used.

As shown in [Table 2], in the cleaning methods that are typical to date and that use, respectively, the APM solution (including the method in which the APM solution is combined with the SPM solution) and the HF aqueous solution, the etch selectivity of the TEOS or BPSG film to the th-SiO₂ film is large. For example, in the APM cleaning, the etch selectivity of the TEOS film to the th-SiO₂ film is 6.4, and the etch selectivity of the BPSG film to the th-SiO₂ film is 38.3.

On the other hand, as shown in [Table 2], in the cleaning methods using the BHF aqueous solution (including the method in which the BHF aqueous solution is combined with the O₃-containing water and the TMAH aqueous solution), the etch selectivity of the TEOS or BPSG film to the th-SiO₂ film is small, as compared to the APM cleaning. Specifically, in the cleaning method using the BHF aqueous solution (hereinafter also referred to as BHF cleaning), the etch selectivity of the TEOS film to the th-SiO₂ film is 2.3, and the etch selectivity of the BPSG film to the th-SiO₂ film is 2.5. That is to say, the etch selectivity of the CVD oxide film to the th-SiO₂ film in the BHF cleaning is half or less of that in the APM cleaning.

Then, the present inventor has evaluated particle removal capabilities of various cleaning methods (a third study). Specifically, a native oxide film formed on an evaluation wafer of Bare-Si was wet-etched using hydrofluoric acid. In this way, the surface of the evaluation wafer obtains a hydrophobic property. Subsequently, about 5000 polystyrene latex (PSL) particles having a grain size of about 0.25 μm were applied onto the evaluation wafer, and then the evaluation wafer was left out for a week so that a native oxide film with a thickness of 1.0 nm was formed on the evaluation wafer. Thereafter, the evaluation wafer was cleaned by a cleaning method to be evaluated, and then the number of PSL particles remaining on the evaluation wafer was measured with a particle counter (with a sensitivity of 0.20 μm or more), to calculate the rate of the PSL particle removal. The result is shown in [Table 3].

TABLE 3

| | rate of PSL particle | rate of PSL particle |
|---|---|---|
| | removal when | removal when |
| | equivalent th-SiO₂ etch | equivalent th-SiO₂ etch |
| | amount is 0.5 nm | amount is 1.0 nm |
| APM | 99.8% | 99.9% |
| 1:1:40 50° C. | (APM 10 min.) | (APM 20 min.) |
| BHF | 98.4% | 99.1% |
| 0.1% HF | (BHF 13 s.) | (BHF 26 s.) |
| 40% NH₄F 23° C. | | |
| BHF(0.1% HF | 99.8% | 99.9% |
| 40% NH₄F 23° C.) + | (BHF 12 s., O₃ 3 min., | (BHF 25 s., O₃ 3 min., |
| O₃(5 ppm 23° C.) + | TMAH 2 min.) | TMAH 2 min.) |
| TMAH(2% 23° C.) | | |

The third study was performed on: the cleaning methods using, respectively, the APM solution and the BHF aqueous solution; and the cleaning method using the combination of the BHF aqueous solution, the O₃-containing water and the TMAH aqueous solution. In the third study, the compositions of and the cleaning temperatures for the APM solution, BHF aqueous solution, O₃-containing water and TMAH aqueous solution are the same as those in the first and second studies. In the third study, each of the cleaning solutions was used in a bath for circulating solutions. To evaluate particle removal capabilities, the amounts of the oxide film etched by the respective cleaning methods (which are converted to etch amounts that would be the case if the oxide film were a thermal oxide film) are set equal. Specifically, the rates of PSL particle removal were calculated in respective cases where the equivalent th-SiO₂ etch amounts are 0.5 nm and 1.0 nm, respectively. In the case where the equivalent th-SiO₂ etch amount is 0.5 nm, the cleaning time in the APM cleaning is 10 minutes, the cleaning time in the BHF cleaning is 13 seconds, and the cleaning time in the cleaning method using a combination of the BHF aqueous solution, O₃-containing water and TMAH aqueous solution (hereinafter also referred to as BHF+O₃+TMAH cleaning) is 12 seconds +3 minutes +2 minutes. In the case where the equivalent th-SiO₂ etch amount is 1.0 nm, the cleaning time in the APM cleaning is 20 minutes, the cleaning time in the BHF cleaning is 26 seconds, and the cleaning time in the BHF+O₃+TMAH cleaning is 25 seconds+3 minutes+2 minutes. Particle removal capabilities were evaluated with the etch amounts of the oxide film set equal because of the following reasons. In an actual process such as resist removal or polymer removal, plasma ashing is performed before cleaning so that a thin oxide film (an ashing oxide film) with a thickness of about 2 to 6 nm is formed on the surface of a wafer (e.g., the surface of a silicon substrate) immediately before cleaning. Thus, it is necessary to examine the correlation between the etch amount of the oxide film and the particle removal capability. In addition, in order to evaluate characteristics of the cleaning methods, it is also necessary to uniformize physical parameters. That is to say, since the particle removal capability of a cleaning method depends greatly on the amount of the underlying film etched by cleaning, it is necessary to compare respective particle removal capabilities, while equalizing etch amounts of the oxide film.

As shown in [Table 3], if etch amounts of the oxide film are set equal, substantially the same excellent capability in particle removal is obtained in any of the cleaning methods. However, the particle removal capability of the BHF cleaning is slightly poorer than that of the APM cleaning. This is because the BHF aqueous solution has a pH around 4, i.e., is acid, while the APM solution has a pH around 10, i.e., is alkaline, and thus in the BHF cleaning, particles are easily adsorbed on or adhered to the wafer resulting from a zeta potential.

On the other hand, as shown in [Table 3], the particle removal capability of the BHF+O₃+TMAH cleaning is substantially the same as that of the APM cleaning. This can be explained by the following reasons. That is to say, if the surface of a wafer (e.g., the surface of a silicon substrate) is cleaned with the BHF aqueous solution before the surface of the silicon substrate is cleaned using an O₃-containing water with an O₃ concentration of about 5 ppm for about three minutes at a temperature of about 23° C., a chemical oxide film is formed on the surface of the silicon substrate, allowing the surface of the silicon substrate to be cleaned using the TMAH solution, while preventing adherence of particles, for example. In the BHF+O₃+TMAH cleaning, the etch rates of the th-SiO₂ film, the TEOS film and the BPSG film obtained by cleaning with the O₃-containing water and the TMAH aqueous solution, respectively, are all 0.1 nm/min. or less and are so small that they may be ignored, as compared to the etch rates of the th-SiO₂ film, the TEOS film and the BPSG film in the BHF cleaning.

From the results shown in [Table 1] through [Table 3], the present inventor has obtained the following conclusion.

That is to say, in a cleaning process performed between the formation of a sidewall and the formation of a silicide layer, if cleaning in which the etch selectivity of a CVD oxide film to a thermal oxide film is 5 or less, e.g., lift-off cleaning using BHF cleaning, is performed instead of the known APM cleaning, then it is possible to secure a cleaning capability (such as a particle removal capability) substantially equal to that in the APM cleaning, while suppressing erosion of the sidewall. If the cleaning capability of a BHF aqueous solution is seriously poor as compared to an APM solution, combination of the BF aqueous solution and other cleaning solutions (e.g., an O₃-containing water and a TMAH aqueous solution) can attain a cleaning capability equal to or higher than that in the APM cleaning.

Specifically, in a cleaning process performed between the formation of a sidewall and the formation of a silicide layer, if the BHF cleaning or the BHF+O₃+TMAH cleaning is performed instead of the known SPM+APM or APM cleaning, erosion of the CVD oxide film forming the sidewall can be reduced by about 50%.

The present invention has been made based on the foregoing findings. Specifically, an inventive method for cleaning a semiconductor device includes the step of: forming a sidewall out of a CVD oxide film on a side face of a gate electrode formed on a semiconductor substrate, and then, with the sidewall exposed, cleaning the semiconductor substrate such that the CVD oxide film has an etch selectivity of 5 or less with respect to a thermal oxide film.

According to the inventive method for cleaning a semiconductor device, in a state where a sidewall made of a CVD oxide film is exposed, i.e., in a cleaning process performed from the formation of the sidewall through the formation of a silicide layer, a semiconductor substrate is cleaned such that the etch selectivity of the CVD oxide film to a thermal oxide film is 5 or less. Thus, erosion of the sidewall can be reduced as intended, as compared to the case where known APM cleaning in which the etch selectivity of the CVD oxide film to a thermal oxide film exceeds 5 is used with the sidewall of the CVD oxide film exposed. Accordingly, when a silicide layer is formed on the surfaces of source/drain regions, it is possible to prevent the silicide layer from extending toward the gate electrode. Thus, even if the semiconductor device is downsized, it is also possible to prevent a leakage current from being caused between the gate electrode and the source or drain region. In addition, if a BHF aqueous solution, for example, is used as a cleaning solution, the surface of the semiconductor substrate is lifted off, thereby removing particles attached to the surface thereof. Further, if a combination of the BHF aqueous solution, an O₃-containing water and a TMAH aqueous solution, for example, is used as a cleaning solution, it is possible to achieve a cleaning capability in removing polymer, resist residues or particles, for example, that is equal to or higher than that achieved in known SPM+APM cleaning. Therefore, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

In the inventive method for cleaning a semiconductor device, the step of cleaning the semiconductor substrate preferably includes the step of lifting off the surface of the semiconductor substrate using a first cleaning solution containing buffered hydrofluoric acid, thereby removing particles attached to the surface of the semiconductor substrate.

Then, the etch selectivity of the CVD oxide film to a thermal oxide film is small in the cleaning step using the first cleaning solution containing buffered hydrofluoric acid, i.e., BHF cleaning, thus ensuring reduction in erosion of the CVD oxide film forming the sidewall. In addition, the semiconductor device can be cleaned as intended.

In this case, the step of cleaning the semiconductor substrate preferably includes the step of cleaning the semiconductor substrate using, respectively, a second cleaning solution containing ozone and a third cleaning solution containing tetramethylammonium hydroxide.

Then, it is possible to achieve a cleaning capability equal to or higher than that in the known SPM+APM cleaning. Thus, the semiconductor device can be further cleaned.

In the inventive method for cleaning a semiconductor device, the gate electrode may be made of polysilicon, polycide, poly-metal or metal.

A first inventive method for fabricating a semiconductor device includes the steps of; forming a gate electrode on a semiconductor substrate; forming a CVD oxide film over the semiconductor substrate and the gate electrode; etching back the CVD oxide film, thereby forming a sidewall out of the CVD film on a side face of the gate electrode; and removing, by ashing, a polymer created during the step of etching back, and then cleaning the semiconductor substrate such that the CVD oxide film has an etch selectivity of 5 or less with respect to a thermal oxide film.

According to the first inventive method for fabricating a semiconductor device, a CVD oxide film formed on a semiconductor substrate provided with a gate electrode is etched back, thereby forming a sidewall on a side face of the gate electrode. Thereafter, a polymer created during the step of etching back is removed by ashing, and then the semiconductor substrate is cleaned using a first cleaning solution such that the etch selectivity of the CVD oxide film to a thermal oxide film is 5 or less. Accordingly, erosion of the sidewall can be reduced as intended, as compared to the case where known APM cleaning in which the etch selectivity of the CVD oxide film to a thermal oxide film exceeds 5 exceeds used to remove ashing residues. In addition, if a BHF aqueous solution or a combination of, for example, the BHF aqueous solution and other cleaning solutions are used as a cleaning solution, particles or polymer residues attached to the substrate surface, for example, can be removed as intended. Thus, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

A second inventive method for fabricating a semiconductor device includes the steps of: forming a gate electrode on a transistor region of a semiconductor substrate; forming a sidewall out of a CVD oxide film on a side face of the gate electrode; forming a resist pattern covering a region except for the transistor region, over the semiconductor substrate having been provided with the sidewall; implanting an impurity into the semiconductor substrate using, as a mask, the resist pattern, the gate electrode and the sidewall, thereby forming source/drain regions; and removing the resist pattern by ashing, and then cleaning the semiconductor substrate such that the CVD oxide film has an etch selectivity of 5 or less with respect to a thermal oxide film.

According to the second inventive method for fabricating a semiconductor device, a sidewall of a CVD oxide film is formed on a side face of a gate electrode formed on a transistor region of a semiconductor substrate, and then the semiconductor substrate is doped with an impurity, using a resist pattern covering a region except for the transistor region, the gate electrode and the sidewall as a mask, thereby defining source/drain regions. Thereafter, the resist pattern is removed by ashing, and then the semiconductor substrate is cleaned such that the etch selectivity of the CVD oxide film to a thermal oxide film is 5 or less. Accordingly, erosion of the sidewall can be reduced as intended, as compared to the case where known APM cleaning in which the etch selectivity of the CVD oxide film to a thermal oxide film exceeds 5 is used to remove ashing residues. In addition, if a BHF aqueous solution or a combination of, for example, the BHF aqueous solution and other cleaning solutions are used for cleaning, particles or resist residues attached to the substrate surface, for example, can be removed as intended. Thus, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

A third inventive method for fabricating a semiconductor device includes the steps of: forming a sidewall out of a CVD oxide film on a side face of a gate electrode formed on a semiconductor substrate; implanting an impurity into parts of the semiconductor substrate located to both sides of the gate electrode, thereby forming source/drain regions; cleaning the semiconductor substrate, having been provided with the sidewall and the source/drain regions, such that the CVD oxide film has an etch selectivity of 5 or less with respect to a thermal oxide film; and conducting a heat treatment on the semiconductor substrate that has been cleaned, thereby activating the impurity contained in the source/drain regions .

According to the third inventive method for fabricating a semiconductor device, a sidewall of a CVD oxide film is formed on a side face of a gate electrode formed on a semiconductor substrate, and then parts of the semiconductor substrate located to both sides of the gate electrode is doped with an impurity, thereby defining source/drain regions. Thereafter, the semiconductor substrate is cleaned such that the etch selectivity of the CVD oxide film to a thermal oxide film is 5 or less, and then a heat treatment is conducted, thereby activating the impurity implanted in the source/drain regions. Accordingly, when pre-cleaning to the heat treatment is performed, erosion of the sidewall can be reduced as intended, as compared to the case where known APM cleaning in which the etch selectivity of the CVD oxide film to a thermal oxide film exceeds 5 is used. In addition, if a BHF aqueous solution or a combination of, for example, the BHF aqueous solution and other cleaning solutions are used for cleaning, the cleaning capability in the pre-cleaning can be sufficiently maintained. Thus, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

An inventive fourth method for fabricating a semiconductor device includes the steps of: forming a sidewall out of a CVD oxide film on a side face of a gate electrode formed on a semiconductor substrate; forming a doped layer to be source/drain regions in parts of the semiconductor substrate located to both sides of the gate electrode; forming an insulating film on the semiconductor substrate having been provided with the sidewall and the doped layer; etching the insulating film using, as a mask, a resist pattern having an opening at least on part of the doped layer, thereby patterning the insulating film; removing the resist pattern by ashing, and then cleaning the semiconductor substrate such that the CVD oxide film has an etch selectivity of 5 or less with respect to a thermal oxide film; and forming a metal silicide layer in part of a surface region of the doped layer subjected to the step of cleaning, the part of the surface region being located outside the insulating film that has been patterned.

According to the fourth inventive method for fabricating a semiconductor device, a sidewall of a CVD oxide film is formed on a side face of a gate electrode formed on a semiconductor substrate, and then source/drain regions are defined in parts of the semiconductor substrate located to both sides of the gate electrode. Subsequently, an insulating film is formed on the semiconductor substrate, and then is etched back using, as a mask, a resist pattern having an opening at least on part of the doped layer, thereby forming a mask for forming a silicide layer. Thereafter, the resist pattern is removed by ashing, and then the semiconductor substrate is cleaned such that the etch selectivity of the CVD oxide film to a thermal oxide film is 5 or less. Accordingly, erosion of the sidewall can be reduced as intended, as compared to the case where the known APM cleaning in which the etch selectivity of the CVD oxide film to a thermal oxide film exceeds 5 is used to remove ashing residues. In addition, if a BHF aqueous solution or a combination of, for example, the BHF aqueous solution and other cleaning solutions are used for cleaning, particles or resist residues attached to the substrate surface, for example, can be removed as intended. Thus, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

An inventive fifth method for fabricating a semiconductor device includes the steps of: forming a sidewall out of a CVD oxide film on a side face of a gate electrode formed on a semiconductor substrate; forming a doped layer to be source/drain regions in parts of the semiconductor substrate located to both sides of the gate electrode; forming, on the semiconductor substrate having been provided with the sidewall and the doped layer, a mask pattern having an opening at least on part of the doped layer; cleaning the semiconductor substrate, having been provided with the mask pattern, such that the CVD oxide film has an etch selectivity of 5 or less with respect to a thermal oxide film; and forming a metal film on the semiconductor substrate that has been cleaned, and then conducting a heat treatment on the semiconductor substrate, thereby causing the metal film and part of the surface of the doped layer located outside the mask pattern to react with each other, to form a metal silicide layer.

According to the fifth inventive method for fabricating a semiconductor device, a sidewall of a CVD oxide film is formed on a side face of a gate electrode formed on a semiconductor substrate, and then source/drain regions are defined in parts of the semiconductor substrate located to both sides of the gate electrode. Subsequently, a mask pattern having an opening at least on part of the doped layer is formed, and then the semiconductor substrate is cleaned such that the etch selectivity of the CVD oxide film to a thermal oxide film is 5 or less. Thereafter, a metal film is formed on the semiconductor substrate, and then a heat treatment is conducted, thereby causing the metal film and part of the surface of the doped layer exposed from the mask pattern to react with each other, to form a metal suicide layer. Accordingly, in performing pre-cleaning before the deposition of the metal film used for forming the suicide layer, erosion of the sidewall can be reduced as intended, as compared to the case where the known APM cleaning in which the etch selectivity of the CVD oxide film to a thermal oxide film exceeds 5 is used. In addition, if a BHF aqueous solution or a combination of, for example, the BHF aqueous solution and other cleaning solutions are used for cleaning, the cleaning capability in the pre-cleaning can be sufficiently maintained. Thus, it is possible to prevent a leakage current caused by erosion of the sidewall, as well as to clean the semiconductor device as intended, allowing fabrication of a very small semiconductor device with stability. As a result, semiconductor devices operating at high speed with low power consumption can be fabricated with a good yield.

In the fourth or fifth method for fabricating a semiconductor device, the metal silicide layer may be a cobalt suicide layer, a titanium suicide layer or a nickel silicide layer.

In the first, second, third, fourth or fifth method for fabricating a semiconductor device, the step of cleaning the semiconductor substrate preferably includes the step of lifting off the surface of the semiconductor substrate using a first cleaning solution containing buffered hydrofluoric acid, thereby removing particles attached to the surface of the semiconductor substrate.

Then, in the step of cleaning using a first cleaning solution containing buffered hydrofluoric acid, i.e., BHF cleaning, the etch selectivity of the CVD oxide film to a thermal oxide film is small. Accordingly, erosion of the CVD oxide film forming the sidewall can be reduced as intended. In addition, the semiconductor device can be cleaned as intended.

In this case, the step of cleaning the semiconductor substrate preferably includes the step of cleaning the semiconductor substrate using, respectively, a second cleaning solution containing ozone and a third cleaning solution containing tetramethylammonium hydroxide.

Then, the cleaning capability equal to or higher than that in the known SPM+APM cleaning can be achieved. Accordingly, the semiconductor device can be further cleaned.

In the first, second, third, fourth or fifth method for fabricating a semiconductor device, the gate electrode may be made of polysilicon, polycide, poly-metal or metal.

### BRIEF DESCRIPTION OF THE DRAWINGS

FIGS. 1A through 1D are cross-sectional views illustrating respective process steps of fabricating a semiconductor device according to a first embodiment of the present invention.

FIGS. 2A through 2C are cross-sectional views illustrating respective process steps of fabricating a semiconductor device according to a second embodiment of the present invention.

FIGS. 3A and 3B are cross-sectional views illustrating respective process steps of fabricating a semiconductor device according to a third embodiment of the present invention.

FIGS. 4A and 4B are cross-sectional views illustrating respective process steps of fabricating a semiconductor device according to the third embodiment.

FIG. 5A schematically illustrates erosion of sidewalls each having an LDD structure in the case where the processes from the formation of the sidewalls, through the formation of a silicide layer to be a contact region are performed using a method for fabricating a semiconductor device according to a comparative example using known SPM+APM cleaning. FIG. 5B schematically illustrates erosion of sidewalls each having an LDD structure in the case where the processes from the formation of the sidewall, through the formation of a suicide layer to be a contact region are performed successively using methods for fabricating a semiconductor device according the first through third embodiments.

### DESCRIPTION OF THE PREFERRED EMBODIMENTS

Embodiment 1

Hereinafter, a method for fabricating a semiconductor device according to a first embodiment of the present invention will be described with reference to the drawings, taking a process for forming a sidewall with an LDD structure as an example. The method for fabricating a semiconductor device of the first embodiment employs an inventive method for cleaning a semiconductor device (see “SUMMARY OF THE INVENTION”).

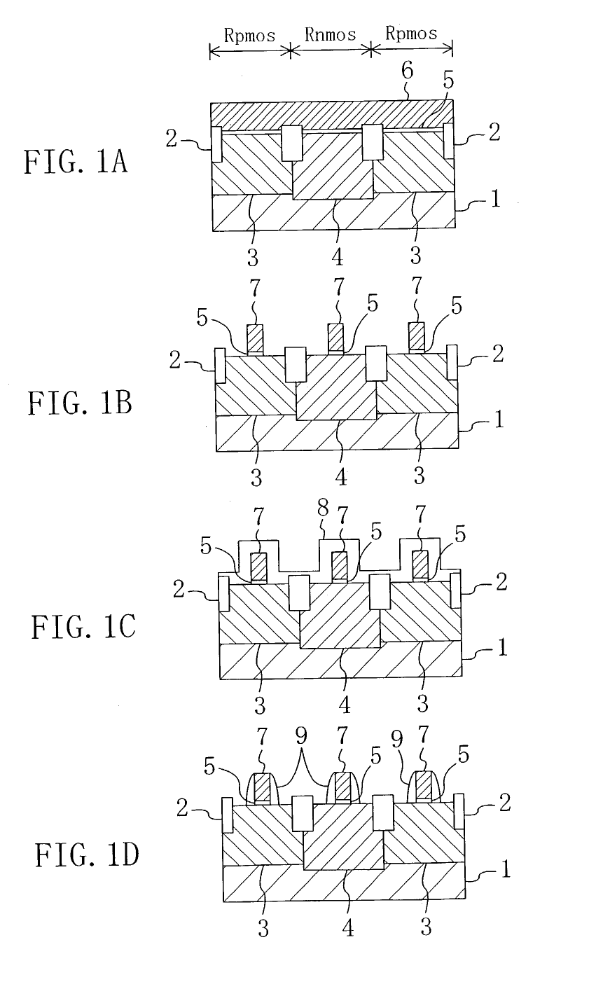

FIGS. 1A through 1D are cross-sectional views illustrating respective process steps of fabricating a semiconductor device according to the first embodiment.

First, as shown in FIG. 1A, an isolation oxide film 2 with a shallow trench isolation (STI) structure is formed on a silicon (Si) substrate 1, thereby defining an n-MOSFET region Rₙₘₒₛ and a p-MOSFET region RₚₘₒₛThen, the p-MOSFET region Rₚₘₒₛ is doped with an n-type impurity, e.g., P, so that an N-well 3 is formed, while the n-MOSFET region Rₙₘₒₛ is doped with a p-type impurity, e.g., B, so that a P-well 4 is formed. Thereafter, a gate oxide film 5 made of a silicon oxide film and a polysilicon film 6 to be gate electrodes are formed in this order on the silicon substrate 1.

Next, as shown in FIG. 1B, the polysilicon film 6 is dry-etched, using, as a mask, a resist pattern (not shown) covering gate electrode regions, thereby forming gate electrodes 7 in the respective MOSFET regions. Thereafter, the resist pattern is removed by sequentially performing ashing and SPM cleaning, and then extension implantation is performed with low energy on each of the MOSFET regions, thereby forming a shallow doped layer (not shown).

Then, as shown in FIG. 1C, a TEOS film 8 is deposited by a CVD process over the entire surface of the silicon substrate 1. Thereafter, the TEOS film 8 is etched back, thereby forming sidewalls 9 on side faces of the respective gate electrodes 7 as shown in FIG. 1D. Thereafter, a polymer created through the etch back process is removed by ashing. Then, for the purpose of removing particles or residual polymer attached to the substrate surface, for example, the silicon substrate 1 is cleaned using, for example, a BHF aqueous solution (0.1% HF concentration by volume; 40% NH₄F concentration by volume) such that the etch selectivity of the TEOS film 8 to a thermal oxide film is 5 or less. Subsequently, to remove organic matter or particles, for example, remaining on the silicon substrate 1, the silicon substrate i is further cleaned using an O₃-containing water and a TMAH aqueous solution one after another. In this case, the cleaning using the TMAH aqueous solution is performed at room temperature.

As described above, in the first embodiment, a TEOS film 8, i.e., a CVD oxide film, formed over a silicon substrate 1 provided with gate electrodes 7 is etched back, thereby forming sidewalls 9 on side faces of the gate electrodes 7. Thereafter, a polymer created during the etching process is removed by ashing, and then the silicon substrate 1 is cleaned such that the etch selectivity of the CVD oxide film to a thermal oxide film is 5 or less. Thus, in removing ashing residues, erosion of the CVD oxide film (i.e., the TEOS film 8) forming the sidewalls 9 can be reduced as intended, as compared to the case where the known APM cleaning in which the etch selectivity of a CVD oxide film to a thermal oxide film exceeds 5 is used. Accordingly, when a silicide layer is formed on the surfaces of the source/drain regions, it is possible to prevent the silicide layer from extending toward the gate electrodes 7. Thus, even if the semiconductor device is downsized, it is also possible to prevent a leakage current from being caused between the gate electrodes 7 and the source/drain regions. In addition, since the BHF aqueous solution is used for cleaning, the surface of the silicon substrate 1 is lifted off, thereby removing particles attached to the surface thereof. Further, since cleaning is performed, using the O₃-containing water and the TMAH aqueous solution one after another after the BHF cleaning, it is possible to achieve a cleaning capability equal to or higher than that achieved in the known SPM+APM cleaning. Therefore, it is possible to prevent a leakage current caused by erosion of the sidewalls 9, as well as to clean the semiconductor device as intended, allowing fabrication of a very small semiconductor device with stability. As a result, semiconductor devices operating at high speed with low power consumption can be fabricated with a good yield.

In the first embodiment, after a polymer created during an etch back process for forming the sidewalls 9 has been removed by ashing, cleaning is performed using the BHF aqueous solution firstly and then subsequently using the O₃-containing water and the TMAH aqueous solution. Alternatively, after ashing has been performed, cleaning may be performed using the TMAH aqueous solution firstly and then subsequently using the BHF aqueous solution and the O₃-containing water. In such a case, it is possible to attain a sufficient cleaning capability, while reducing erosion of the sidewalls 9, as compared to the known SPM+APM cleaning.

In addition, in the first embodiment, polysilicon is used as a material for the gate electrodes 7. However, the present invention is not limited to this specific embodiment and any other conductive material such as polycide, poly-metal or metal may also be used.

Embodiment 2

Hereinafter, a method for fabricating a semiconductor device according to a second embodiment of the present invention will be described with reference to the drawings, taking, as an example, processes from the step of implanting impurities for forming source/drain regions through the step of heat treatment for activating the impurities after the formation of a sidewall with an LDD structure,. The method for fabricating a semiconductor device of the second embodiment employs the inventive method for cleaning a semiconductor device (see “SUMMARY OF THE INVENTION”). It is assumed that, in the second embodiment, the formation of the sidewalls 9 and the preceding processes have been completed using the method for fabricating a semiconductor device according to the first embodiment as shown in FIGS. 1A through 1D.

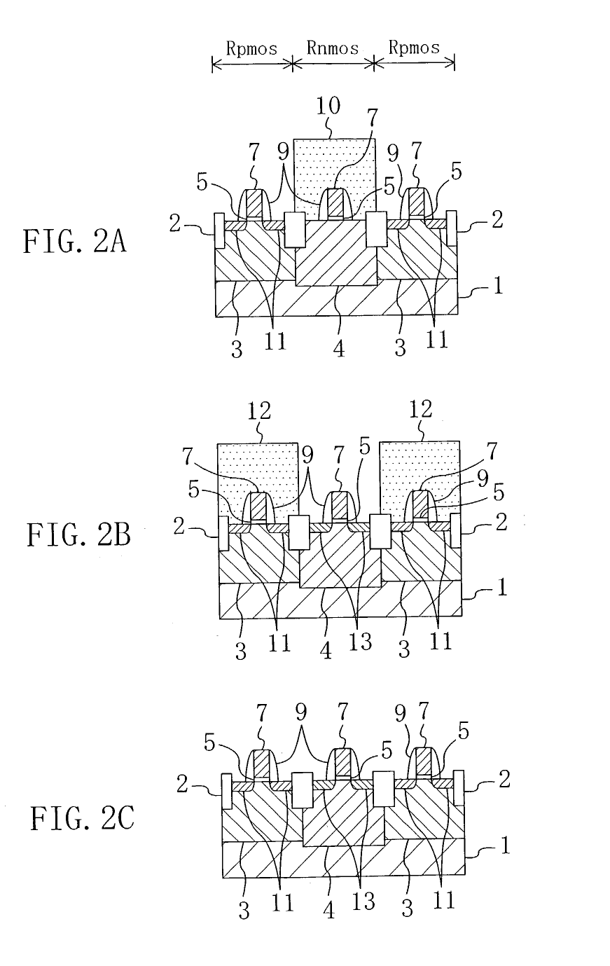

FIGS. 2A through 2C are cross-sectional views illustrating respective process steps of fabricating a semiconductor device according to the second embodiment.

First, as shown in FIG. 2A, a first resist pattern 10 is formed to cover the n-MOSFET region Rₙₘₒₛ, i.e., the P-well 4. Then, the p-MOSFET region Rₚₘₒₛ is doped with a p-type impurity, e.g., B, using, as a mask, the first resist pattern 10, part of the gate electrodes 7 and the sidewalls 9 on the p-MOSFET region Rₚₘₒₛ, , thereby forming a p-type doped layer 11 to be source/drain regions for a p-MOSFET.

Thereafter, the first resist pattern 10 is removed by sequentially performing ashing and SPM cleaning. At this time, an ashing oxide film (not shown) is formed on the surface of the silicon substrate 1 through the ashing. Subsequently, to remove particles or ashing residues such as resist residues attached to the substrate surface, the silicon substrate 1 is cleaned using, for example, a BHF aqueous solution (0.1% HF concentration by volume; 40% NH₄F concentration by volume) such that the etch selectivity of the CVD film (specifically, the TEOS film 8) forming the sidewalls 9 to a thermal oxide film is 5 or less. More specifically, about 0.5 nm (equivalent th-SiO₂ etch amount) of the ashing oxide film on the substrate surface is etched with the BHF aqueous solution, i.e., the ashing oxide film is lifted off, thereby removing ashing residues. Thereafter, to remove organic matter or particles, for example, remaining on the silicon substrate 1, the silicon substrate 1 is cleaned using an O₃-containing water and a TMAH aqueous solution one after another. In this case, the cleaning using the TMAH aqueous solution is performed at room temperature.

Next, as shown in FIG. 2B, a second resist pattern 12 is formed to cover the p-MOSFET region Rₚₘₒₛ, i.e., the N-well 3. Then, the n-MOSFET region Rₙₘₒₛ is doped with an n-type impurity, e.g., As, using the second resist pattern 12, part of the gate electrodes 7 and the sidewalls 9 on the n-MOSFET region Rₙₘₒₛ, as a mask, thereby forming an n-type doped layer 13 to be source/drain regions for an n-MOSFET.

Thereafter, the second resist pattern 12 is removed by sequentially performing ashing and SPM cleaning. At this time, an ashing oxide film (not shown) is formed on the surface of the silicon substrate 1 through the ashing. Subsequently, to remove particles or ashing residues such as resist residues attached to the substrate surface, the silicon substrate 1 is cleaned using, for example, a BHF aqueous solution (0.1% HF concentration by volume; 40% NH₄F concentration by volume) such that the etch selectivity of the TEOS film 8 forming the sidewalls 9 to a thermal oxide film is 5 or less. More specifically, about 0.5 nm (equivalent th-SiO₂ etch amount) of the ashing oxide film on the substrate surface is etched with a BHF aqueous solution so that the ashing oxide film is lifted off, thereby removing ashing residues. Thereafter, to further clean the silicon substrate 1, the silicon substrate 1 is cleaned using an O₃-containing water and a TMAH aqueous solution one after another. In this case, the cleaning using the TMAH aqueous solution is performed at room temperature.

Then, as shown in FIG. 2C, to activate an impurity contained in each of the p- and n-type doped regions 11 and 13, the silicon substrate 1 is subjected to heat treatment, e.g., rapid thermal annealing (RTA). In this case, immediately before the RTA, pre-cleaning for cleaning the silicon substrate 1 is performed using, for example, a BHF aqueous solution (0.1% HF concentration by volume; 40% NH₄F concentration by volume) such that the etch selectivity of the TEOS film 8 forming the sidewalls 9 to a thermal oxide film is 5 or less. More specifically, about 0.2 nm (equivalent th-SiO₂ etch amount) of the ashing oxide film on the substrate surface is etched with a BHF aqueous solution so that paticles, for example, attached to the substrate surface are removed by lift-off. Subsequently, to remove organic matter, for example, remaining on the silicon substrate 1, the silicon substrate 1 is cleaned using an O₃-containing water and a TMAH aqueous solution one after another. In this case, the cleaning using the TMAH aqueous solution is performed at room temperature.

As described above, in the second embodiment, the first or second resist pattern 10 or 12 used as a mask during impurity implantation for forming source/drain regions is removed by ashing, and then the silicon substrate 1 is cleaned such that the etch selectivity of the CVD oxide film to a thermal oxide film is 5 or less. Thus, in removing ashing residues, erosion of the CVD oxide film (i.e., the TEOS film 8) forming the sidewalls 9 can be reduced as intended, as compared to the case where the known APM cleaning in which the etch selectivity of the CVD oxide film to a thermal oxide film exceeds 5 is used. In addition, immediately before heat treatment for activating an impurity contained in the p-or n-type doped layer 11 or 13 to be source/drain regions, pre-cleaning is performed on the silicon substrate 1 such that the etch selectivity of the CVD oxide film to a thermal oxide film is 5 or less. In this manner, during the pre-cleaning, erosion of the sidewalls 9 can be reduced as intended, as compared to the case where the known APM cleaning in which the etch selectivity of the CVD oxide film to a thermal oxide film exceeds 5 is used. Accordingly, when a silicide layer is formed on the surfaces of the source/drain regions, it is possible to prevent the suicide layer from extending toward the gate electrodes 7. Thus, even if the semiconductor device is downsized, it is also possible to prevent a leakage current from being caused between the gate electrodes 7 and the source/drain regions. In addition, since the BHF aqueous solution is used in the respective cleaning processes described above, the surface of the silicon substrate 1 is lifted off, thereby removing particles, for example, attached to the surface thereof Further, since cleaning is performed, using the O₃-containing water and the TMAH aqueous solution one after another, after the cleaning using the BHF aqueous solution, it is possible to achieve a cleaning capability equal to or higher than that achieved in the known SPM+APM cleaning. Therefore, it is possible to prevent a leakage current caused by erosion of the sidewalls 9, as well as to clean the semiconductor device as intended, allowing fabrication of a very small semiconductor device with stability. As a result, semiconductor devices operating at high speed with low power consumption can be fabricated with a good yield.

In the second embodiment, the first or second resist pattern 10 or 12 used as a mask for impurity implantation is removed by ashing, and then cleaning is performed using the BHF aqueous solution firstly and then using the O₃-containing water and the TMAH aqueous solution one after another. Alternatively, after ashing, cleaning may be performed using the TMAH aqueous solution firstly and then using the BHF aqueous solution and the O₃-containing water one after another. In such a case, it is possible to attain a sufficient cleaning capability, while reducing erosion of the sidewalls 9, as compared to the known SPM+APM cleaning.

In addition, in the second embodiment, immediately before heat treatment for activating an impurity contained in the p- or n-type doped layer 11 or 13, cleaning is performed using the BHF aqueous solution firstly and then using the O₃-containing water and the TMAH aqueous solution one after another. Alternatively, immediately before the heat treatment, cleaning may be performed using the TMAH aqueous solution firstly and then using the BHF aqueous solution and the O₃-containing water one after another. In such a case, it is also possible to attain a sufficient cleaning capability, while reducing erosion of the sidewalls 9, as compared to the known SPM+APM cleaning.

Embodiment 3

Hereinafter, a method for fabricating a semiconductor device according to a third embodiment of the present invention will be described with reference to the drawings, taking, as an example, the step of forming a silicide layer to be a contact region after the formation of a sidewall with an LDD structure. The method for fabricating a semiconductor device of the third embodiment employs an inventive method for cleaning a semiconductor device (see “SUMMARY OF THE INVENTION”). It is assumed that, in the third embodiment, the formation of the p- and n-type doped layers 11 and 13 and the preceding processes have been completed using the method for fabricating a semiconductor device according to the first embodiment shown in FIGS. 1A through 1D and the method for fabricating a semiconductor device according to the second embodiment shown in FIGS. 2A through 2C.

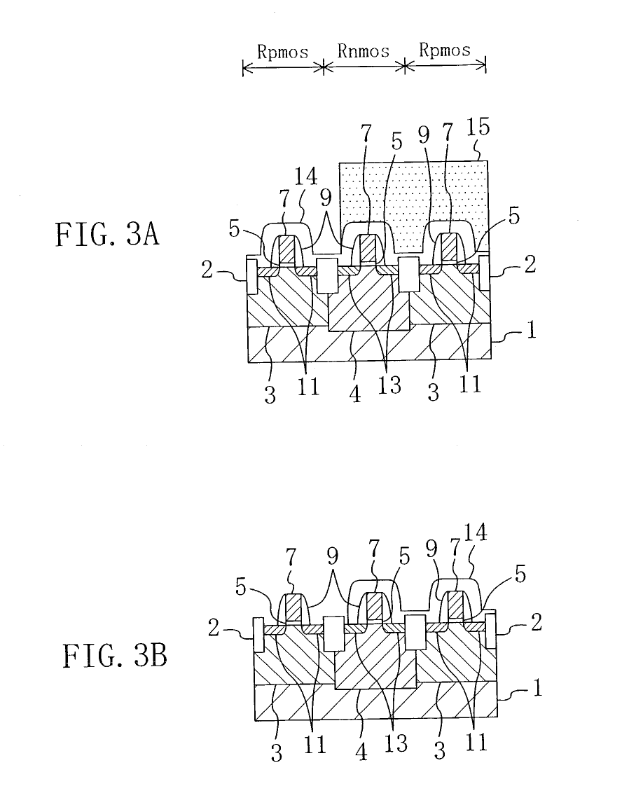

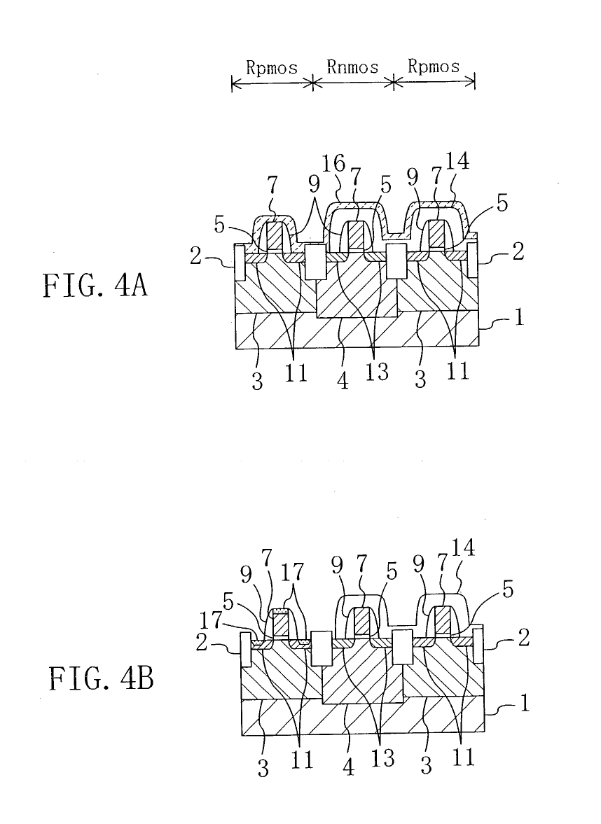

FIGS. 3A and 3B and FIGS. 4A and 4B are cross-sectional views illustrating respective process steps of fabricating a semiconductor device according to the third embodiment.

First, as shown in FIG. 3A, a silicon oxide film 14 is deposited by a CVD process over the entire surface of the silicon substrate 1. Then, a resist pattern 15 is formed to cover a region except for a silicide region (i.e., a non-silicide region).

Next, as shown in FIG. 3B, the silicon oxide film 14 is wet-etched using the resist pattern 15 as a mask, thereby removing part of the silicon oxide film 14 located in the silicide region (specifically, part of the p-MOSFET region Rₚₘₒₛ) In this manner, the p-type doped layer 11 and the gate electrodes 7 in the silicide region are exposed from the patterned silicon oxide film 14. Thereafter, the resist pattern 15 that has been used as an etching mask is removed by sequentially performing ashing and SPM cleaning. At this time, an ashing oxide film (not shown) is formed on the surface of the silicon substrate 1 through the ashing. Subsequently, to remove particles or ashing residues such as resist residues attached to the substrate surface, the silicon substrate 1 is cleaned using, for example, a BHF aqueous solution (0.1% HF concentration by volume; 40% NH₄F concentration by volume) such that the etch selectivity of the TEOS film 8 forming the sidewalls 9 to a thermal oxide film is 5 or less. More specifically, about 0.2 nm (equivalent th-SiO₂ etch amount) of the substrate surface with the ashing oxide film is etched with a BHF aqueous solution, so that ashing residues are removed by lift-off. Thereafter, to remove organic matter or particles, for example, remaining on the silicon substrate 1, the silicon substrate 1 is cleaned using an O₃-containing water and a TMAH aqueous solution one after another. In this case, the cleaning using the TMAH aqueous solution is performed at room temperature.

Then, as shown in FIG. 4A, a silicide-layer-formation metal film 16 in which a TiN film and a Co film are stacked in this order from above is deposited over the entire surface of the silicon substrate 1. In this case, immediately before the silicide-layer-formation metal film 16 is deposited, pre-cleaning for cleaning the silicon substrate 1 is performed using, for example, a BHF aqueous solution (0.1% HF concentration by volume; 40% NH₄F concentration by volume) such that the etch selectivity of the TEOS film 8 forming the sidewalls 9 to a thermal oxide film is 5 or less. More specifically, about 0.2 nm (equivalent th-SiO₂ etch amount) of the substrate surface with the ashing oxide film is etched with a BHF aqueous solution so that particles, for example, attached to the substrate surface are removed by lift-off Thereafter, to remove organic matter, for example, remaining on the silicon substrate 1, the silicon substrate 1 is cleaned using an O₃-containing water and a TMAH aqueous solution one after another. In this case, the cleaning using the TMAH aqueous solution is performed at room temperature.

Then, RTA is performed on the silicon substrate 1. Thus, as shown in FIG. 4B, the Co film as a lower layer of the silicide-layer-formation metal film 16, and the respective surfaces of the p-type doped layer 11 and the gate electrodes 7 that are located outside the patterned silicon oxide film 14 (i.e., the surface of the silicon layer in the silicide region), react with each other, thereby selectively forming a Co silicide layer 17. Thereafter, the TiN film as an upper film, and an unreacted part of the Co film, of the silicide-layer-formation metal film 16 are selectively removed, thus completing the salicide process.

As described above, in the third embodiment, a resist pattern 15 for forming a mask for use in the formation of a silicide layer (i.e., the patterned silicon oxide film 14) is removed by ashing, and then the silicon substrate 1 is cleaned such that the etch selectivity of the CVD oxide film to a thermal oxide film is 5 or less. In this manner, in removing ashing residues, erosion of the CVD oxide film (i.e., the TEOS film 8 forming the sidewalls 9 can be reduced as intended, as compared to the case where the known APM cleaning in which the etch selectivity of the CVD oxide film to a thermal oxide film exceeds 5 is used. In addition, immediately before the silicide-layer-formation metal film 16 is deposited, pre-cleaning is performed on the silicon substrate 1 such that the etch selectivity of the CVD oxide film to a thermal oxide film is 5 or less. In this manner, during the pre-cleaning, erosion of the sidewalls 9 can be reduced as intended, as compared to the case where the known APM cleaning in which the etch selectivity of the CVD oxide film to a thermal oxide film exceeds 5 is used. Accordingly, when a Co silicide layer 17 is formed on the surface of the p-type doped layer 11, i.e., the surfaces of the source/drain regions, it is possible to prevent the Co silicide layer 17 from extending toward the gate electrodes 7. Thus, even if the semiconductor device is downsized, it is also possible to prevent a leakage current from being caused between the gate electrodes 7 and the source/drain regions. In addition, since the BHF aqueous solution is used in the respective cleaning processes described above, the surface of the silicon substrate 1 is lifted off, thereby removing particles, for example, attached to the surface thereof Further, since cleaning is performed using the BHF aqueous solution firstly, and then using the O₃-containing water and the TMAH aqueous solution one after another, it is possible to achieve a cleaning capability equal to or higher than that achieved in the known SPM+APM cleaning. Therefore, it is possible to prevent a leakage current caused by erosion of the sidewalls 9, as well as to clean the semiconductor device as intended, allowing fabrication of a very small semiconductor device with stability. As a result, semiconductor devices operating at high speed with low power consumption can be fabricated with a good yield.

In the third embodiment, the resist pattern 15 used for forming a mask for use in the formation of a silicide layer is removed by ashing, and then cleaning is performed using the BHF aqueous solution firstly and then using the O₃-containing water and the TMAH aqueous solution one after another. Alternatively, after ashing, cleaning may be performed using the TMAH aqueous solution firstly and then using the BHF aqueous solution and the O₃-containing water one after another. In such a case, it is possible to attain a sufficient cleaning capability, while reducing erosion of the sidewalls 9, as compared to the known SPM+APM cleaning.

In addition, in the third embodiment, immediately before the silicide-layer-formation metal film 16 is deposited, cleaning is performed using the BHF aqueous solution firstly and then using the O₃-containing water and the TMAH aqueous solution one after another. Alternatively, immediately before the silicide-layer-formation metal film 16 is deposited, cleaning may be performed using the TMAH aqueous solution firstly and then using the BHF aqueous solution and the O₃-containing water one after another. In such a case, it is also possible to attain a sufficient cleaning capability, while reducing erosion of the sidewalls 9, as compared to the known SPM+APM cleaning.

In the third embodiment, the cobalt (Co) silicide layer 17 is formed in the silicide region. Alternatively, any other metal silicide layer such as titanium silicide layer or nickel silicide layer may also be formed.

Hereinafter, comparison between the amount of erosion of sidewalls, each having an LDD structure, when the processes from the formation of the sidewalls, through the formation of a silicide layer to be a contact region are performed using successively the semiconductor-device fabricating methods according to the first through third embodiments, and the amount of erosion of sidewalls when the inventive BHF+O₃+TMAH cleaning in the semiconductor-device fabricating methods according to the first through third embodiments is replaced by the known SPM+APM cleaning (a comparative example), will be described.

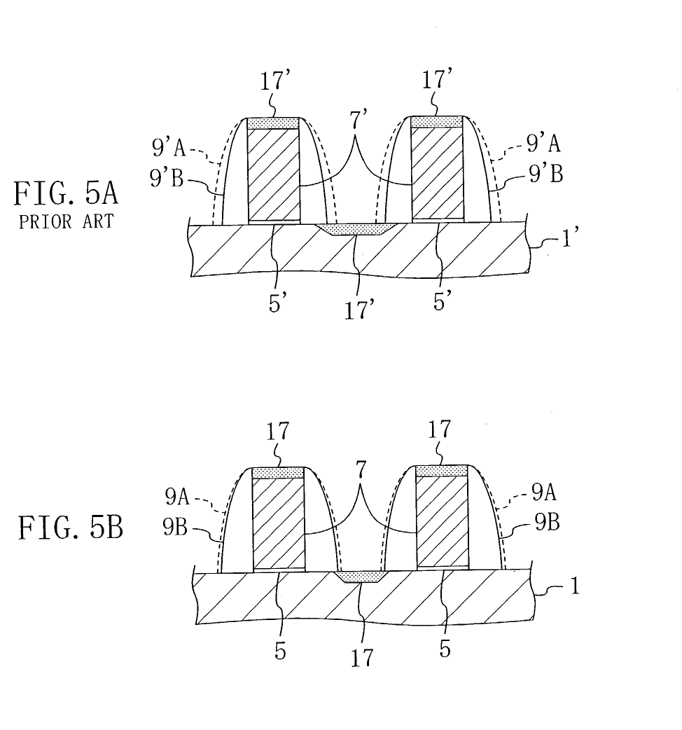

FIG. 5A schematically illustrates the amount of erosion of sidewalls in the comparative example. FIG. 5B schematically illustrates the amount of erosion of sidewalls when the methods in the first through third embodiments are used successively. In the comparative example, each member corresponding to a component of the first through third embodiments is identified by the same reference numeral (labeled with a prime, however) and the description thereof will be omitted herein. In FIGS. 5A and 5B, members other than those required for description are not shown.

As shown in FIG. 5A, in the comparative example, APM cleaning in which the etch selectivity of a CVD oxide film to a thermal oxide film is large is used, so that sidewalls 9′B are greatly eroded as compared to as-formed sidewalls 9′A at the time when a Co silicide layer 17′ is formed,. As a result, the Co suicide layer 17′ expands toward the gate electrodes 7′ so that a leakage current is more easily caused between the gate electrodes 7′ and the source/drain regions.

On the other hand, as shown in FIG. 5B, in a situation where the first through third embodiments are successively used, BHF cleaning in which the etch selectivity of a CVD oxide film to a thermal oxide film is small is used, so that sidewalls 9B are hardly eroded as compared to as-formed sidewalls 9A at the time when a Co silicide layer 17 is formed. Specifically, if BHF+O₃+TMAH cleaning in which the equivalent th-SiO₂ etch amount is about 0.5 nm is performed six times, for example, between the formation of the sidewalls and the formation of the silicide layer, the erosion of the one of the sidewalls 9 formed on one side of the gate electrodes 7 can be reduced by about 10 nm, as compared to the case where SPM+APM cleaning in which the equivalent th-SiO₂ etch amount is the same, i.e., about 0.5 nm, is performed six times in the comparative example. As a result, the Co silicide layer 17 does not enlarge toward the gate electrodes 7 so that a leakage current is less likely to be caused between the gate electrodes 7 and the source/drain regions.

What is claimed is:

1. A method for cleaning a semiconductor device, the method comprising the step of forming a sidewall out of a CVD oxide film on a side face of a gate electrode formed on a semiconductor substrate, and then, with the sidewall exposed, cleaning the semiconductor substrate such that the CVD oxide film has an etch selectivity of 5 or less with respect to a thermal oxide film.

2. The method for cleaning a semiconductor device of claim 1, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

3. The method for cleaning a semiconductor device of claim 2, wherein the step of cleaning the semiconductor substrate includes the step of cleaning the semiconductor substrate using, respectively, a second cleaning solution containing ozone and a third cleaning solution containing tetramethylammonium hydroxide.

4. The method for cleaning a semiconductor device of claim 1, wherein the gate electrode is made of polysilicon, polycide, poly-metal or metal.

5. A method for fabricating a semiconductor device, the method comprising the steps of:
forming a gate electrode on a semiconductor substrate;
forming a CVD oxide film over the semiconductor substrate and the gate electrode;
etching back the CVD oxide film, thereby forming a sidewall out of the CVD film on a side face of the gate electrode; and
removing, by ashing, a polymer created during the step of etching back, and then cleaning the semiconductor substrate such that the CVD oxide film has an etch selectivity of 5 or less with respect to a thermal oxide film.

6. The method for fabricating a semiconductor device of claim 5, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

7. The method for fabricating a semiconductor device of claim 6, wherein the step of cleaning the semiconductor substrate includes the step of cleaning the semiconductor substrate using, respectively, a second cleaning solution containing ozone and a third cleaning solution containing tetramethylammonium hydroxide.

8. The method for fabricating a semiconductor device of claim 5, wherein the gate electrode is made of polysilicon, polycide, poly-metal or metal.

9. A method for fabricating a semiconductor device, the method comprising the steps of:
forming a gate electrode on a transistor region of a semiconductor substrate;
forming a sidewall out of a CVD oxide film on a side face of the gate electrode;
forming a resist pattern covering a region except for the transistor region, over the semiconductor substrate having been provided with the sidewall;
implanting an impurity into the semiconductor substrate using, as a mask, the resist pattern, the gate electrode and the sidewall, thereby forming source/drain regions; and
removing the resist pattern by ashing, and then cleaning the semiconductor substrate such that the CVD oxide film has an etch selectivity of 5 or less with respect to a thermal oxide film.

10. The method for fabricating a semiconductor device of claim 9, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

11. The method for fabricating a semiconductor device of claim 10, wherein the step of cleaning the semiconductor substrate includes the step of cleaning the semiconductor substrate using, respectively, a second cleaning solution containing ozone and a third cleaning solution containing tetramethylammonium hydroxide.

12. The method for fabricating a semiconductor device of claim 9, wherein the gate electrode is made of polysilicon, polycide, poly-metal or metal.

13. A method for fabricating a semiconductor device, the method comprising the steps of:
forming a sidewall out of a CVD oxide film on a side face of a gate electrode formed on a semiconductor substrate;
implanting an impurity into parts of the semiconductor substrate located to both sides of the gate electrode, thereby forming source/drain regions;
cleaning the semiconductor substrate, having been provided with the sidewall and the source/drain regions, such that the CVD oxide film has an etch selectivity of 5 or less with respect to a thermal oxide film; and
conducting a heat treatment on the semiconductor substrate that has been cleaned, thereby activating the impurity implanted in the source/drain regions

14. The method for fabricating a semiconductor device of claim 13, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

15. The method for fabricating a semiconductor device of claim 14, wherein the step of cleaning the semiconductor substrate includes the step of cleaning the semiconductor substrate using, respectively, a second cleaning solution containing ozone and a third cleaning solution containing tetramethylammonium hydroxide.

16. The method for fabricating a semiconductor device of claim 13, wherein the gate electrode is made of polysilicon, polycide, poly-metal or metal.

17. A method for fabricating a semiconductor device, the method comprising the steps of:
forming a sidewall out of a CVD oxide film on a side face of a gate electrode formed on a semiconductor substrate;
forming a doped layer to be source/drain regions in parts of the semiconductor substrate located to both sides of the gate electrode;
forming an insulating film on the semiconductor substrate having been provided with the sidewall and the doped layer;
etching the insulating film using, as a mask, a resist pattern having an opening at least on part of the doped layer, thereby patterning the insulating film;
removing the resist pattern by ashing, and then cleaning the semiconductor substrate such that the CVD oxide film has an etch selectivity of 5 or less with respect to a thermal oxide film; and
forming a metal suicide layer in part of a surface region of the doped layer subjected to the step of cleaning, the part of the surface region being located outside the insulating film that has been patterned.

18. The method for fabricating a semiconductor device of claim 17, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

19. The method for fabricating a semiconductor device of claim 18, wherein the step of cleaning the semiconductor substrate includes the step of cleaning the semiconductor substrate using, respectively, a second cleaning solution containing ozone and a third cleaning solution containing tetramethylammonium hydroxide.

20. The method for fabricating a semiconductor device of claim 17, wherein the gate electrode is made of polysilicon, polycide, poly-metal or metal.

21. The method for fabricating a semiconductor device of claim 17, wherein the metal silicide layer is a cobalt silicide layer, a titanium silicide layer or a nickel silicide layer.

22. A method for fabricating a semiconductor device, the method comprising the steps of:
forming a sidewall out of a CVD oxide film on a side face of a gate electrode formed on a semiconductor substrate;
forming a doped layer to be source/drain regions in parts of the semiconductor substrate located to both sides of the gate electrode;
forming, on the semiconductor substrate having been provided with the sidewall and the doped layer, a mask pattern having an opening at least on part of the doped layer;
cleaning the semiconductor substrate, having been provided with the mask pattern, such that the CVD oxide film has an etch selectivity of 5 or less with respect to a thermal oxide film; and
forming a metal film on the semiconductor substrate that has been cleaned, and then conducting a heat treatment on the semiconductor substrate, thereby causing the metal film and part of the surface of the doped layer located outside the mask pattern to react with each other, to form a metal silicide layer.

23. The method for fabricating a semiconductor device of claim 22, wherein the step of cleaning the semiconductor substrate includes the step of lifting off the surface of the semiconductor substrate using a first cleaning solution containing buffered hydrofluoric acid, thereby removing particles attached to the surface of the semiconductor substrate.

24. The method for fabricating a semiconductor device of claim 23, wherein the step of cleaning the semiconductor substrate includes the step of cleaning the semiconductor substrate using, respectively, a second cleaning solution containing ozone and a third cleaning solution containing tetramethylammonium hydroxide.

25. The method for fabricating a semiconductor device of claim 22, wherein the gate electrode is made of polysilicon, polycide, poly-metal or metal.

26. The method for fabricating a semiconductor device of claim 22, wherein the metal silicide layer is a cobalt silicide layer, a titanium silicide layer or a nickel silicide layer.
